(19) United States
(12) Patent Application Publication
(10) Pub. No.: US 2004/0180551 A1
(43) Pub. Date: Sep. 16, 2004

(54) Carbon hard mask for aluminum interconnect fabrication

(76) Inventors: Peter John Biles, Orlando, FL (US); Stephen Ward Downey, Orlando, FL (US); Thomas Craig Esry, Orlando, FL (US)

Correspondence Address: BEUSSE BROWNLEE WOLTER MORA & MAIRE, P. A., 390 NORTH ORANGE AVENUE, SUITE 2500, ORLANDO, FL, 32801, US

(21) Appl. No.: 10/388,349

(22) Filed: Mar. 13, 2003

(51) Int. Cl. H01L 21/302

(52) U.S. Cl. 438/706

(57) ABSTRACT

A carbon hard mask (62) for patterning an aluminum layer (58) in a microelectronics device (50). The carbon hard mask will release carbon during a reactive ion etch process, thereby eliminating the need to use CHF₃ as a passivation gas. Portions of the carbon hard mask remaining after the RIE process are removed during the subsequent strip passivation process without the need for a separate mask removal step.

### FIELD OF THE INVENTION

This invention relates generally to semiconductor wafer processing and more particularly to a method and an in-process device for forming high aspect ratio aluminum interconnects on a semiconductor wafer.

### BACKGROUND OF THE INVENTION

There is a continuing demand in the semiconductor industry for lower cost and improved reliability in both the end-use devices and the tools and processes used to produce those devices. The ability to create semiconductor devices with sub-micron sized features has greatly reduced the cost and has improved the reliability of current devices when compared to similar devices produced just years ago. Continued reduction of dimensions has been made possible, in part, by advances in lithography, such as the use of more advanced cameras and the development of more sensitive photoresist materials. However, the accuracy of the lithographic pattern must then be reproduced onto the underlying layer. The use of anisotropic etching processes such as reactive ion etching (RIE) has allowed the industry to transfer very small images in photoresist to an underlying metal layer. RIE removes material by exposing a surface to a combination of chemical etchants and a stream of plasma ions. In order to control the slope of the resulting metal layer side surface, it is desirable to have as thin a layer of photoresist as possible, limited however, by the relative removal rates of the masking photoresist and the exposed metal layer during the etching process.

FIG. 1 illustrates a prior art semiconductor device 10 at a selected stage of a manufacturing process. Device 10 includes a semiconductor wafer such as silicon (Si) wafer 12 having an active device region. An insulation layer in the interconnection region such as silicon dioxide (SiO₂) layer 14 is formed thereon. A metal layer 16 such as aluminum (Al) or aluminum copper (AlCu) is disposed on the silicon dioxide layer 14, and is shown in FIG. 1 has having been partially removed by etching to form an interconnect structure 18. The width of interconnect 18 is defined by the width W of a photoresist layer 20 disposed over the metal layer 16. The metal layer 16 is separated from the silicon dioxide layer 14 by a titanium (Ti) layer 22 disposed on the silicon dioxide layer 14 and a first titanium nitride (TiN) layer 24 disposed on the titanium layer 22. In order to eliminate problems associated with back reflection of light during the photolithography process, it is known to form an anti-reflective coating (ARC) layer between the photoresist layer 20 and the metal layer 16. A second titanium nitride layer 26 and a layer of silicon oxy-nitride (SiON) 28 interact to function as an anti-reflective coating layer 27. It is believed that a small amount of corrosion products may accumulate on the top surface of metal layer 16 during the processing of the device, thereby creating a thin interface layer 29.

The materials and dimensions of device 10 and the processes used to manufacture such a structure are known in the art. For example, the metal layer 16 may range from about 0-1% copper, and may be deposited by known processes such as physical vapor deposition (PVD) to a thickness from 5,000-7,000 Angstroms. The titanium and titanium nitride barrier layers 22,24,26 may be deposited by PVD or chemical vapor deposition (CVD) to a thickness of 300-500 Angstroms. The silicon nitride layer 28 may be deposited by CVD or plasma enhanced CVD to a thickness of 300-350 Angstroms. The pattern formed in the photoresist layer 20 selectively exposes or protects portions of the underlying layers to cause the formation of interconnect structure 18 during the reactive ion etching process.

RIE regiments used to form interconnect 18 commonly use Cl₂ and BCl₃, as etchant gasses and CHF₃ or other halocarbon as a passivation gas. Passivation is a concept known in the art for depositing a buffer layer on the surfaces of a material being exposed to a reactive ion etch. As the horizontal surface of the material is removed by the combination of chemical and sputtering effects generated by the vertically oriented ions produced in the RIE process, the newly exposed side vertical surface 30 is protected from the ion stream by the overlying masking layer. However, the newly exposed vertical surfaces 30 continue to be exposed to the effects of the chemical etchants. This isotropic chemical effect results in the undesirable removal of material in the horizontal direction during the desirable removal of material in the vertical direction, resulting in the potential formation of a notch or undercut 32 in the interconnect 18. Passivation gasses supply a layer of protective material to retard the isotropic effect, thereby limiting the removal of material in the horizontal direction. Passivation gas CHF₃ provides a source of carbon that is deposited on the newly exposed vertical surfaces 30 of the metal layer 16. The carbon serves as a buffer against the continued isotropic removal of material in the horizontal direction. The use of CHF₃ is known to result in the deposition of polymers on the surfaces of the etch chamber, leading to the necessity for frequent cleaning of the chamber and the possibility of chamber failures or wafer defects due to flaking of the polymer from the chamber parts.

Reactive ion etch processes are known to remove a portion of the thickness of a photoresist mask. Accordingly, high aspect ratio aluminum features must be etched with either a thick photoresist mask or with a highly selective etch process that will conserve a thin mask throughout the entire etch process. Thick conventional photoresist masks are not feasible for small features due to lithography constraints. High selectivity etch processes used with thin photoresist masks typically use the troublesome CHF₃ passivation gas. Thin dielectric hard masks such as silicon oxy-nitride or silicon dioxide are also typically used with a polymer-forming passivation gas. Moreover, a dielectric hard mask must be removed or penetrated by a subsequent additional processing step to ensure electrically continuity with the underlying metal layer.

### SUMMARY OF THE INVENTION

A semiconductor wafer fabrication process has been developed that eliminates the need for the use of the troublesome CHF₃ passivation gas during the reactive ion etching of a metal layer and that further provides for the removal of the hard mask used to define an interconnect structure during a subsequent strip passivation step without the need for a separate mask removal processing step.

A device is described herein at a stage of fabrication as including a layer of metal disposed over a substrate and a patterned layer of carbon disposed as a mask over the layer of metal.

A hard mask is described herein that exhibits a removal rate during a reactive ion etch of an underlying metal layer that is less than a removal rate that would be exhibited by a photoresist mask during the same reactive ion etch, and that exhibits a removal rate during a subsequent strip passivation step that is sufficiently high to remove any portion of the hard mask remaining over the metal layer after the reactive ion etch.

A semiconductor device fabrication method is described herein as including: depositing a layer of carbon over a layer of metal; forming a pattern in the layer of carbon to expose selected portions of the layer of metal; and performing a reactive ion etch to remove exposed portions of the layer of metal.

### BRIEF DESCRIPTION OF THE DRAWINGS

These and other advantages of the invention will be more apparent from the following description in view of the drawings that show:

FIG. 1 is a partial cross-sectional view of a prior art semiconductor wafer showing a metal interconnect at a stage of fabrication.

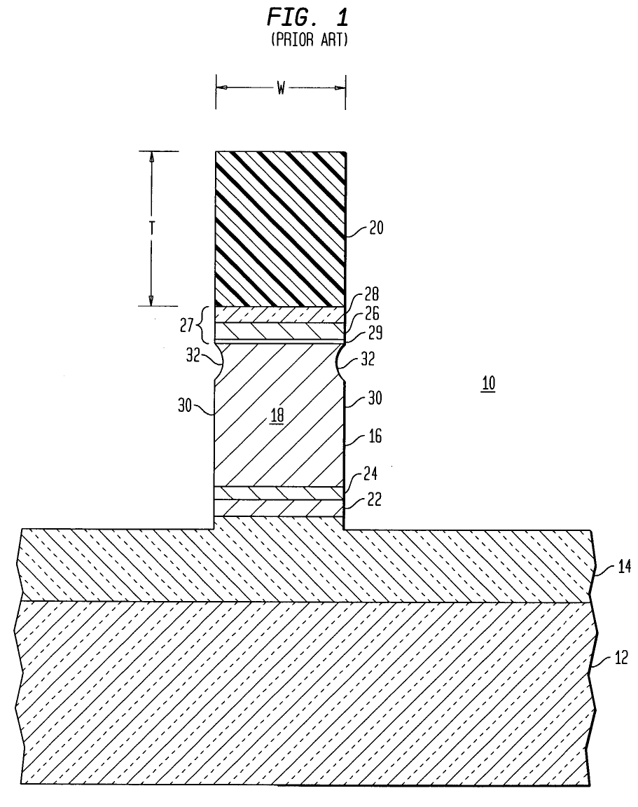

FIG. 2 is a partial cross-sectional view of a semiconductor wafer at a stage of fabrication wherein a photoresist layer has been patterned.

FIG. 3 is a partial cross-sectional view of the semiconductor wafer of FIG. 2 at a stage of fabrication wherein a carbon hard mask has been patterned over a metal layer.

FIG. 4 is a partial cross-sectional view of the semiconductor wafer of FIG. 2 at a stage of fabrication wherein regions of the metal layer have been selectively removed to form a metal interconnect structure.

### DETAILED DESCRIPTION OF THE INVENTION

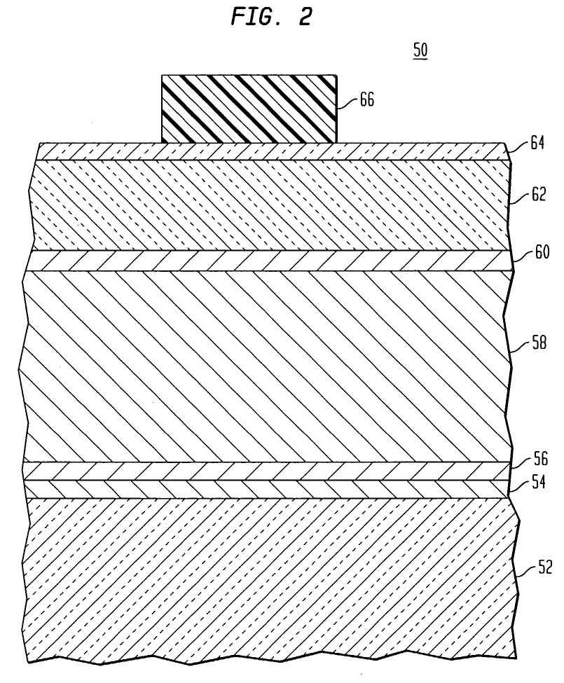

A semiconductor device 50 is illustrated in FIG. 2 at a stage of fabrication wherein a plurality of layers of materials are disposed on a substrate 52 prior to the fabrication of a metal interconnect structure on the substrate 52. Substrate 52 may be silicon, silicon dioxide, or other semiconductor or insulator material depending upon the particular application. Barrier layers of titanium 54 and titanium nitride 56 are first disposed on a silicon substrate 52, each to a typical thickness of about 27.5 nm, for example. Next, a layer of metal 58 such as aluminum or aluminum copper is deposited to a typical thickness of about 600 nm. A further barrier layer of titanium nitride 60 is then deposited to a thickness of about 50 nm. A hard mask layer of carbon 62 is then deposited to a typical thickness of about 200 nm or in other embodiments to thickness as high as 400-500 nm. A dielectric antireflective coating layer (DARC) of silicon nitride 64 having a thickness of about 10-25 nm is then deposited over the layer of carbon 62, followed by a layer of photoresist 66. Processes known in the art are used to deposit these layers. The layer of photoresist 66 is illustrated in FIG. 2 after having been patterned by a known photolithography process.

The terms “layer of carbon” and “carbon film” are used herein to describe materials whose mass is primarily carbon, whose structure is defined primarily by carbon atoms, or whose physical and chemical properties are dominated by its carbon content. These terms are meant to exclude materials that are simply mixtures or compounds that include carbon, for example dielectric materials such as carbon-doped silicon oxy-nitride, carbon-doped silicon oxide or carbon-doped polysilicon. These terms do include graphite, charcoal and halocarbons, for example.

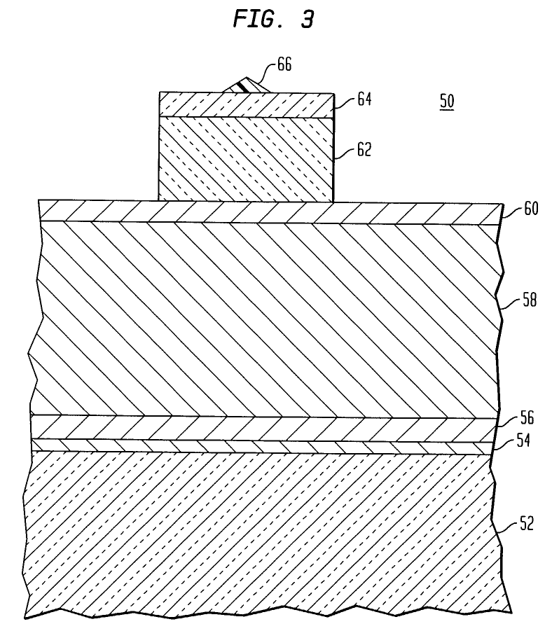

Layer 64 serves several functions. First, it serves as an antireflective coating during the photoresist patterning process, although the layer of carbon 58 would serve a similar function if the DARC layer 64 were not used. Layer 64 also allows the layer of photoresist 66 to be stripped without damage to the underlying carbon layer 62 in the event that the photoresist pattern is misshaped or misaligned and must be reapplied. Furthermore, layer 64 functions as a mask during the patterning of the underlying carbon layer 62. FIG. 3 illustrates device 50 at a further stage of fabrication wherein regions of the DARC layer 64 that were exposed through the pattern of the photoresist layer 66 have been removed, such as in an Ar—CF₄ environment, and further where the resulting pattern in the DACR layer 64 has been used as a mask for the removal of selected regions of the carbon layer 62. The regions of carbon layer 62 exposed through the DARC layer mask may be removed in an environment such as Ar—0₂ that is selective to the DARC layer 64. This step will also remove all or most of the photoresist layer 66.

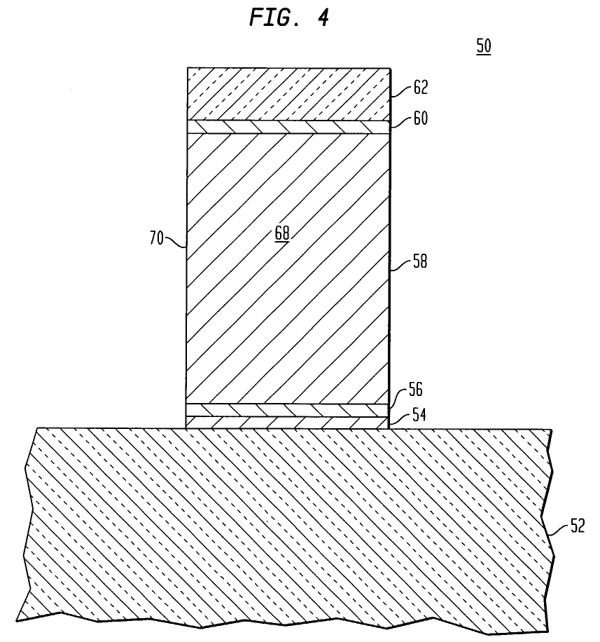

FIG. 4 illustrates the device 50 at a further stage of fabrication upon completion of a reactive ion etch regiment utilizing Cl₂ and BCl₃ etchant gasses for the removal of the exposed portions of layers 60, 58, 56 and 54 to form interconnect structure 68. This etching process will also remove any remaining portions of photoresist layer 66, the DARC layer 64 and a portion of the carbon hard mask layer 62. The erosion of the carbon layer 62 provides a degree of passivation in the etch environment to protect against undercutting of the newly exposed side walls 70 of interconnect 68. A more benign passivation gas such as nitrogen may be added to the etchant environment as needed for additional passivation. No CHF₃ or other halogenated hydrocarbon passivation gas need be added during this etching step because of the availability of carbon from the carbon layer 62, thereby extending the time or number of wafers between etch chamber cleanings and potentially lowering the number of wafer defects resulting from polymer spalling. While carbon-doped dielectric hard masks (i.e. silicon-based materials containing some carbon) have been used in the prior art to supply passivation carbon during a metal etching process, there has been no teaching of a carbon film capable of releasing enough carbon to eliminate the need for CHF₃ in the etch chemistry.

It is known that it is necessary to process a semiconductor device following a chlorine-based etch of an aluminum or aluminum-copper layer in order to remove residual amounts of chlorine and photoresist from the metal surfaces. Failure to perform such cleaning will result in the rapid corrosion of the metal in the presence of moisture due to the formation of HCl on the metal surface. A common method of performing such cleaning is a strip passivation process wherein the wafer is exposed to an oxygen and water-containing plasma. The highly reactive OH radicals readily displace chlorine that is bound to the aluminum, and the Al—O bond is very stable and does not allow the corrosion reaction.

Advantageously, the portions of the carbon hard mask 62 remaining after the RIE step will be removed in such a strip passivation process without the need for a separate processing step, unlike prior art schemes utilizing hard masks formed of SiON and SiO₂ which require a special process step for the removal of the hard mask. The TiN layer 60 is oxidized slightly in the strip passivation process, which is normal. Thus, the present scheme enables the subtractive etching of a metal line with a thin hard mask but without the use of CHF₃ passivation gas and without the need for a separate processing step for the removal of the hard mask. Alternatively, any remaining portions of the carbon layer 62 may be removed in a water-oxygen environment with or without the use of fluorine, if so desired, as the fluorine can also passivates the metal and thus prevents corrosion.

The carbon layer 62 may be a carbon film deposited by the methods described in U.S. Pat. No. 6,423,384, which is hereby incorporated by reference herein. The carbon film 62 may include concentrations of hydrogen, nitrogen and/or oxygen as byproducts of the deposition process, for example as described in the '384 patent, without detracting from the utility of the present invention. The carbon film 62 may have an amorphous structure such as charcoal or polytetrafluoroethylene or it may have a 2D planar crystalline structure such as graphite. A 3D diamond crystalline structure in the carbon layer would make it more difficult to remove residual portions of the mask and thus would be undesirable.

Various embodiments of the carbon film 62 may exhibit different dielectric constant values. Whereas the incorporated United States patent is focused on a low dielectric constant material, the present invention may include embodiments wherein the carbon film 62 may be considered a conductor, thus providing protection against current-induced material damage during the RIE process.

Without regard to the particular crystalline structure of the carbon, or to the dielectric constant of the layer, or to other materials included therein, the present invention contemplates a layer of carbon 62 that will release free carbon into the etch chamber environment during the RIE step to serve as a passivation material for the newly exposed metal line side walls 70. The present invention further contemplates a hard mask carbon material that will exhibit a removal rate in a reactive ion etch environment that is less than that of a polymer photoresist material, thereby allowing a relatively thinner mask to be used. A typical photoresist removal rate in a typical RIE environment may be on the order of 2000 Angstroms/minute, whereas the removal rate of a carbon layer 62 of the present invention may be on the order of 1000 or less Angstroms/minute or preferably less than about 500 Angstroms/minute. For comparative purposes, a prior art silicon nitride or silicon dioxide hard mask may exhibit a removal rate under similar conditions of about 300-500 Angstroms/minute. The present invention further contemplates that the layer of carbon 62 will exhibit a removal rate in the subsequent strip passivation step that is sufficiently high to remove remaining portions of the carbon hard mask 62 without a further separate mask removal step. The removal rate of the carbon layer 62 during a typical strip passivation process is significantly greater than that of a prior art silicon nitride or silicon dioxide hard mask (which are essentially unaffected by strip passivation), and it may approach the removal rate of photoresist material under such conditions, i.e. about 10,000 Angstroms/minute. A combination of these features allows carbon layer 62 to function as a thin hard mask, to provide a source of passivation carbon during RIE, to eliminate the need for CHF₃ passivation gas during RIE, and to be removed during a planned downstream process without the addition of a special hard mask removal step.

The features of the present invention extend the capabilities of existing aluminum back end tool sets. Prior art processes are used to provide aluminum features with maximum aspect ratios of no more than 5:1. Because the present carbon hard mask can be made much thinner than a prior art photoresist mask, aluminum features having aspect ratios of greater than 5:1 can be produced, such as at least 6:1, or at least 7:1, or at least 8:1, or at least 9:1 and possibly even as high as 10:1, limited only by the mechanical properties of the materials. This allows aluminum interconnects to be used in certain applications where previously only dual damascene copper technology was thought to be practical. The mask of the present invention is more resistant to an etch process than prior art masks and it therefore allows the user more flexibility in the selection of operating process parameters. In addition to the utilization of cleaner passivation gasses, other parameter such as applied RF power can be engaged over a greater range than with conventional photoresist masks. During a reactive ion etch, the bias power affects the ion energy striking the wafer. A higher bias power can improve the verticality of an etched profile, however, it will also erode the mask at a higher rate. The present invention allows the user to specify a higher bias power than is otherwise practical with prior art masks, thereby giving a more vertical, anisotropic profile to the etched feature. This is especially useful for those features that are isolated a fair distance (e.g. >1 μm) from other features. Such isolated features may include not only isolated side of metal lines, but also small pillars of metal used for interlayer interconnection, and importantly, layouts where isolated lines approach the pillars at minimum spacing allowed by the design of the part being fabricated.

While the preferred embodiments of the present invention have been shown and described herein, it will be obvious that such embodiments are provided by way of example only. Numerous variations, changes and substitutions will occur to those of skill in the art without departing from the invention herein. The various layers of material and dimensions that are described herein represent a descriptive embodiment of the present invention and they are not meant to be limiting. Accordingly, it is intended that the invention be limited only by the spirit and scope of the appended claims.

We claim as our invention:

1. A device at a stage of fabrication comprising:
a layer of metal disposed over a substrate; and
a patterned layer of carbon disposed as a mask over the layer of metal.

2. The device of claim 1, wherein the layer of carbon comprises carbon and at least one of the group of nitrogen and hydrogen.

3. The device of claim 1, wherein the layer of carbon comprises hydrogenated carbon.

4. The device of claim 1, wherein the layer of carbon comprises a halocarbon.

5. The device of claim 1, wherein the layer of carbon comprises polytetrafluoroethylene.

6. The device of claim 1, wherein the layer of carbon comprises amorphous carbon.

7. The device of claim 1, wherein the layer of carbon comprises a planar crystalline structure.

8. The device of claim 1, further comprising a layer of an anti-reflective coating material disposed as a mask over the layer of carbon.

9. The device of claim 1, wherein the layer of metal comprises one of the group of aluminum and aluminum copper.

10. The device of claim 1, wherein the layer of metal comprises aluminum.

11. The device of claim 1, further comprising a feature profile having an aspect ratio of greater than 5:1 formed in the layer of metal by an etch through the mask.

12. The device of claim 1, further comprising a feature profile having an aspect ratio of between 5:1 and 10:1 formed in the layer of metal by an etch through the mask.

13. The device of claim 1, further comprising a feature profile having an aspect ratio of greater than 6:1 formed in the layer of metal by an etch through the mask.

14. In a semiconductor device fabrication process, a hard mask that exhibits a removal rate during a reactive ion etch of an underlying metal layer that is less than a removal rate that would be exhibited by a photoresist mask during the same reactive ion etch, and that exhibits a removal rate during a subsequent strip passivation step that is sufficiently high to remove any portion of the hard mask remaining over the metal layer after the reactive ion etch.

15. The device of claim 14, wherein the hard mask comprises a carbon film.

16. The device of claim 14, wherein the hard mask comprises hydrogenated carbon.

17. The device of claim 14, wherein the hard mask comprises carbon and nitrogen.

18. The device of claim 14, wherein the hard mask comprises a halocarbon.

19. The device of claim 14, wherein the hard mask comprises polytetrafluoroethylene.

20. The device of claim 14, wherein the hard mask comprises a planar crystalline structure.

21. The device of claim 14, wherein the hard mask comprises an amorphous structure.

22. A semiconductor device fabrication method comprising:
depositing a layer of carbon over a layer of metal;
forming a pattern in the layer of carbon to expose selected portions of the layer of metal; and
performing an etch to remove exposed portions of the layer of metal.

23. The method of claim 22, wherein the etch is a reactive ion etch performed without using CHF₃ as a passivation gas.

24. The method of claim 22, wherein the etch is a reactive ion etch performed without using a halogenated hydrocarbon as a passivation gas.

25. The method of claim 23, wherein the etch is performed using nitrogen as a passivation gas during the reactive ion etch.

26. The method of claim 22, further comprising removing all portions of the layer of carbon remaining over the layer of metal after completion of the etch during a strip passivation step.

27. The method of claim 22, further comprising:
depositing a layer of antireflective material over the layer of carbon; and
forming a pattern in the antireflective material as a mask for forming the pattern in the layer of carbon.

28. A semiconductor device comprising:
a substrate;
a metal layer comprising aluminum disposed on the substrate;
a feature profile formed in the metal layer by an etch process to have an aspect ratio greater than 5:1.

29. The semiconductor device of claim 28, wherein the aspect ratio is at least 6:1.

30. The semiconductor device of claim 28, wherein the aspect ratio is between 5:1 and 10:1.

31. The semiconductor device of claim 28, wherein the aspect ratio is at least 7:1.
